(19) United States
(12) Patent Application Publication
(10) Pub. No.: US 2012/0217467 A1
(43) Pub. Date: Aug. 30, 2012

(54) BURIED CHANNEL FINFET SONOS WITH IMPROVED P/E CYCLING ENDURANCE

(75) Inventors: Shyue Seng (Jason) Tan, Singapore (SG); Eng Huat Toh, Singapore (SG); Elgin Quek, Singapore (SG)

(73) Assignee: GLOBALFOUNDRIES Singapore Pte. Ltd., Singapore (SG)

(21) Appl. No.: 13/034,256

(22) Filed: Feb. 24, 2011

(51) Int. Cl. H01L 29/06; H01L 27/12; H01L 21/762

(52) U.S. Cl. 257/9; 438/479; 257/324; 257/E21.561; 257/E27.112; 257/E29.005; 977/762

(57) ABSTRACT

A Fin FET SONOS device is formed with a full buried channel. Embodiments include forming p-type silicon fins protruding from a first oxide layer, an n-type silicon layer over exposed surfaces of the fins, a second oxide layer, a nitride layer, and a third oxide layer sequentially on the n-type silicon layer, and a polysilicon layer on the third oxide layer. Embodiments include etching a silicon layer to form the fins and forming the oxide on the silicon layer. Different embodiments include: etching a silicon layer on a BOX layer to form the fins; forming the fins with a rounded top surface; and forming nano-wires surrounded by an n-type silicon layer, a first oxide layer, a nitride layer, a second oxide layer, and a polysilicon layer over a BOX layer.

### TECHNICAL FIELD

The present disclosure relates to non-volatile memory devices with improved program/erase (P/E) cycling endurance. The present disclosure is particularly applicable to FinFET silicon-oxide-nitride-oxide-silicon (SONOS) type devices.

### BACKGROUND

SONOS type devices have been proposed to solve the scaling limitation of floating-gate memory devices. However, unlike floating-gate devices, planar SONOS-type devices do not employ gate coupling ratio designs and exhibit the same bottom oxide electrical field and top oxide electrical field when uncharged, which leads to lower P/E efficiency. Therefore, FinFET SONOS devices, as shown in FIG. 1, have been introduced by taking advantage of good DC performance, such as better short-channel effects and higher drive current, to improve programming and erase cycle speed. As illustrated in FIG. 1, FinFET SONOS includes p-type silicon (Si) substrate 101, shallow trench isolation (STI) region 103, nitride layer 105 sandwiched between portions of STI region 103, and polysilicon 107. Such type devices can exhibit controlled programming and erasing times within 20 microseconds (μsec) and 2 milliseconds (msec), respectively, with a 5 volt (V) memory window.

To further improve the endurance, a partial buried channel (a thin N-type channel 201 on a P-type substrate, with regions 203 remaining surface channels) has been employed on a FinFET SONOS, as illustrated in FIG. 2. This allows a depleted mode transistor with a channel below the Si surface, and therefore provides improved cell immunity against Si interface defects or properties degradation (such as Dit) during the P/E cycle. However, regions 203 continue to be susceptible to interface defects. Partial buried channel devices show significantly improved endurance over the conventional surface channel devices. As illustrated in FIG. 3A, large area planar device 301 (during programming) and 303 (during erasing) exhibits good intrinsic performance, as compared with surface channel device 305 (during programming) and 307 (during erasing), at +18 V, 200 μsec (for programming) and −16 V and 10 msec (for erasing). However, adverting to FIG. 3B, even with the FinFET buried-channel, endurance degrades for a sub-30 nanometer (nm) device 309 (during programming) and 311 (during erasing), as compared with surface channel device 313 (during programming) and 315 (during erasing), as Vₜ starts to degrade, or shift, after 500 P/E cycles. This is attributed to a higher fringing electrical field at the edges and corner-related defects. In addition, the partial buried channel fails to provide full immunity against interfacial defects. As defects build up, the device may experience a program or erase failure, which is permanent and non-recoverable.

A need therefore exists for methodology enabling fabrication of non-volatile memories with improved P/E cycling endurance, and the resulting devices.

### SUMMARY

An aspect of the present disclosure is a method of fabricating a full buried channel FinFET SONOS device.

Another aspect of the present disclosure is an n-type full buried channel FinFET SONOS device.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method comprising: forming p-type silicon fins protruding from a first oxide layer; forming an n-type silicon layer over exposed surfaces of the fins; forming a second oxide layer, a nitride layer, and a third oxide layer sequentially on the n-type silicon layer; and forming a polysilicon layer on the third oxide layer.

Aspects of the present disclosure include forming the n-type silicon layer by n-type plasma doping the fins or by epitaxially growing in-situ n-doped silicon on the fins. Further aspects include forming the fins in a p-type silicon substrate; and forming the first oxide layer on the p-type silicon substrate around the fins. Other aspects include forming the first oxide layer by: depositing an oxide over the substrate and the fins; and time etching the oxide to a thickness of 2 nm to 20 nm. Additional aspects include forming the p-type silicon fins by: forming a hard mask on the p-type silicon substrate; patterning a photoresist on the hard mask with openings; etching the p-type silicon substrate through the openings in the patterned photoresist; and removing the photoresist. Another aspect includes planarizing the deposited oxide and subsequently time etching the oxide; and removing the hard mask after time etching the oxide, prior to forming n-type silicon layer. Further aspects include forming the p-type silicon fins by: forming a hard mask on the p-type silicon substrate; patterning a photoresist with openings on the hard mask; anisotropically etching followed by isotropically etching the p-type silicon substrate through the openings, thereby forming fins; removing the photoresist and the hard mask; and creating a round top surface for each fin. Other aspects include creating the round top surface for each fin by H₂ treating. Additional aspects include forming a p-type silicon substrate on a bulk oxide (BOX) layer; and forming the fins in the silicon substrate. Another aspect includes forming the p-type silicon fins by: forming a hard mask on the p-type silicon substrate; patterning a photoresist with openings on the hard mask; anisotropically etching followed by isotropically etching the p-type silicon substrate through the openings, thereby forming fins; removing the photoresist and the hard mask; and creating a round top surface for each fin. Other aspects include creating the round top surface for each fin by H₂ treating.

Another aspect of the present disclosure is a device including: a first oxide layer; p-type silicon fins protruding from the first oxide layer; an n-type silicon layer over exposed surfaces of the fins; a second oxide layer, a nitride layer, and a third oxide layer sequentially formed on the n-type silicon layer; and a polysilicon layer on the third oxide layer.

Aspects include a device having a p-type silicon substrate under the first oxide layer, wherein the fins extend from the p-type silicon substrate and through the first oxide layer. Further aspects include a device having fins, each of which has a rounded top surface. Other aspects include a device having a bulk oxide layer as the first oxide layer; and each fin has a rounded top surface.

Another aspect of the present disclosure is a method including: forming a p-type silicon substrate on a bulk oxide layer; forming nano-wires from the silicon substrate; forming an n-type silicon layer around the nano-wires; forming a second oxide layer, a nitride layer, and a third oxide layer sequentially on the n-type silicon layer; and forming a polysilicon layer on the third oxide layer.

Aspects include forming the nano-wires by: patterning a photoresist on the silicon substrate; etching the silicon substrate through the patterned photoresist and undercutting the bulk oxide layer; removing the photoresist; and H₂ treating each fin. Further aspects include forming the n-type silicon layer by n-type plasma doping the fins or by epitaxially growing in-situ n-doped silicon on the fins.

Another aspect of the present disclosure is a device including p-type silicon nano-wires; an n-type silicon layer around the nano-wires; a first oxide layer, a nitride layer, and a second oxide layer sequentially formed on the n-type silicon layer; and a polysilicon layer on the third oxide layer. Aspects include a device having a bulk oxide layer under the polysilicon layer, wherein the bulk oxide layer is undercut below the nano-wires.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates a prior art FinFET SONOS device;

FIG. 2 schematically illustrates a prior art partial buried channel FinFET SONOS device;

FIG. 3A illustrates a comparison of performance for a partial buried channel FinFET large area planar device versus a surface channel device;

FIG. 3B illustrates a comparison of performance for a sub 30 nm partial buried channel FinFET device versus a surface channel device;

FIGS. 4A through 4H schematically illustrate a process flow for fabricating an n-type full buried channel, in accordance with an exemplary embodiment;

FIGS. 5A through 5I schematically illustrate a process flow for fabricating an Ω-shaped n-type full buried channel, in accordance with another exemplary embodiment;

FIGS. 6A through 6G schematically illustrate a process flow for fabricating an Ω-shaped n-type full buried channel on a silicon on insulator (SOI) substrate, in accordance with another exemplary embodiment; and

FIGS. 7A through 7F schematically illustrate a process flow for fabricating an n-type full buried channel nano-wire, in accordance with another exemplary embodiment.

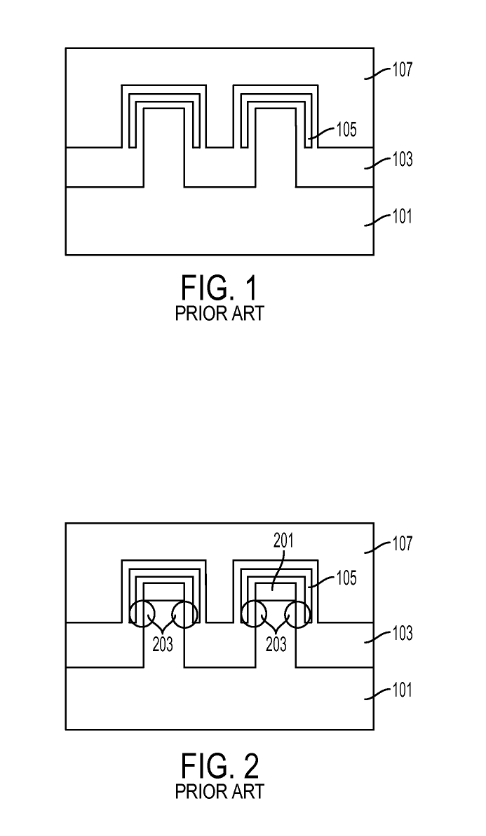

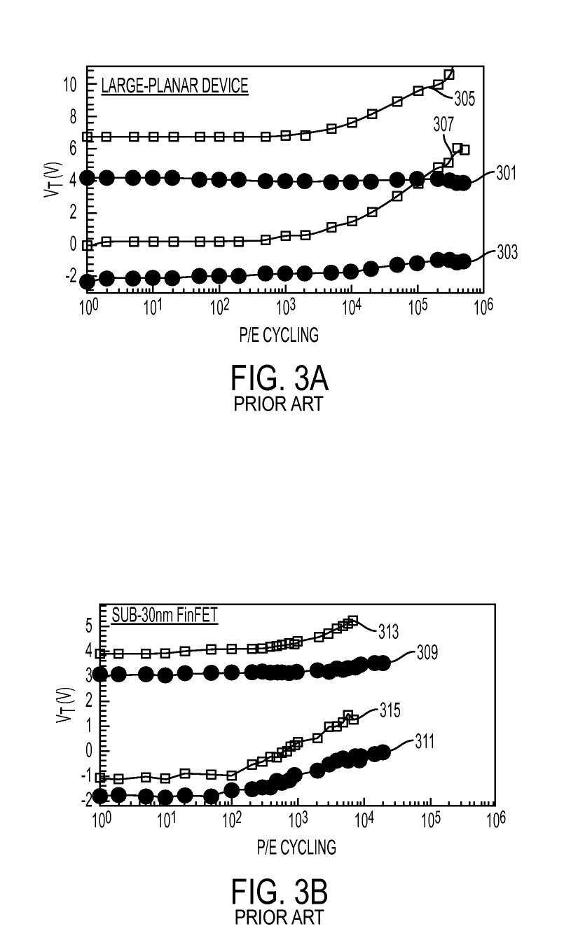

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves, inter alia, the problem of Vₜ shift with P/E cycle attendant upon partial buried channel FinFET SONOS devices. In accordance with embodiments of the present disclosure, after p-type silicon fins are formed, an n-type silicon layer is formed over the entire exposed surface of the fins. Subsequently, an oxide layer, a nitride layer, a second oxide layer, and polysilicon are formed on the n-type silicon layer. The n-type silicon forms a full buried channel, which provides full immunity against interface degradation during the P/E cycle, thereby improving P/E cycle endurance. In addition, by forming a rounded top surface on the fins prior to forming the n-type silicon layer, fringing field and corner-related defects introduced by edges may be reduced.

Methodology in accordance with embodiments of the present disclosure includes forming p-type silicon fins protruding from a first oxide layer, forming an n-type silicon layer over exposed surfaces of the fins, forming a second oxide layer, a nitride layer, and a third oxide layer sequentially on the n-type silicon layer, and forming a polysilicon layer on the third oxide layer.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

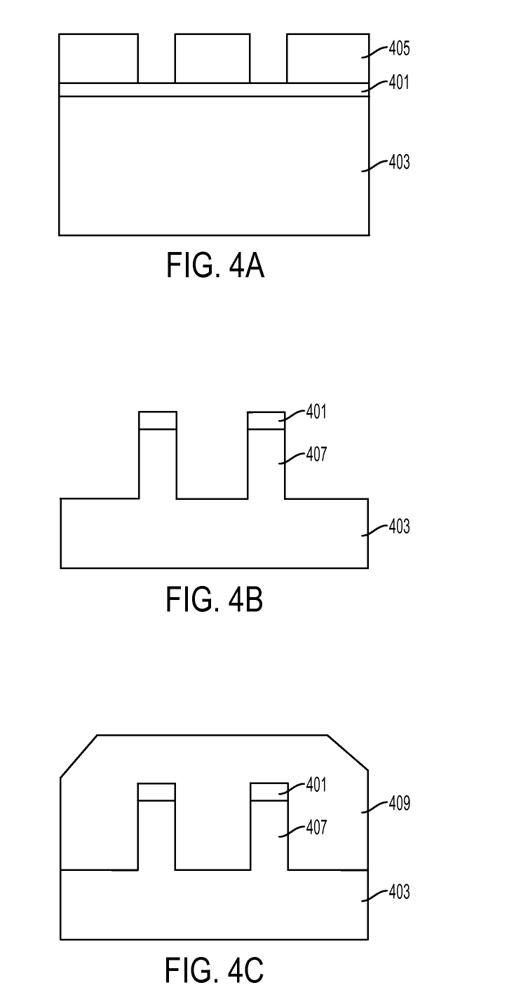

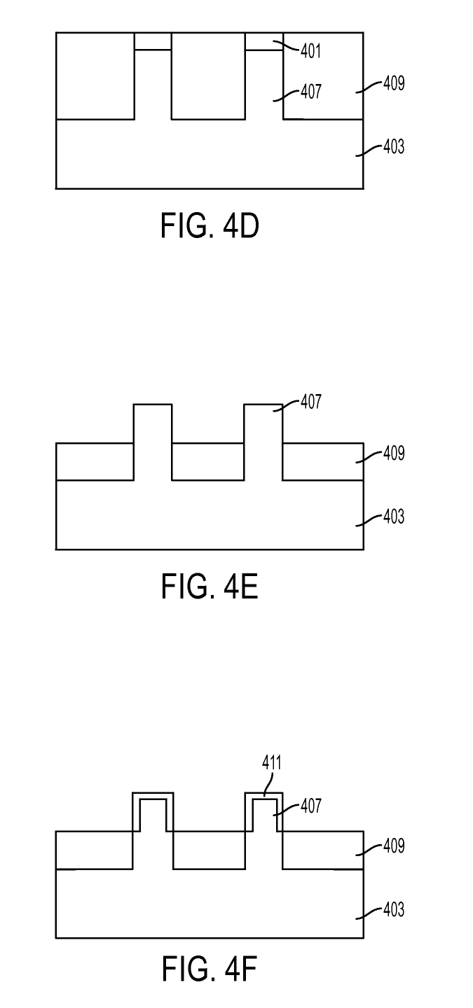

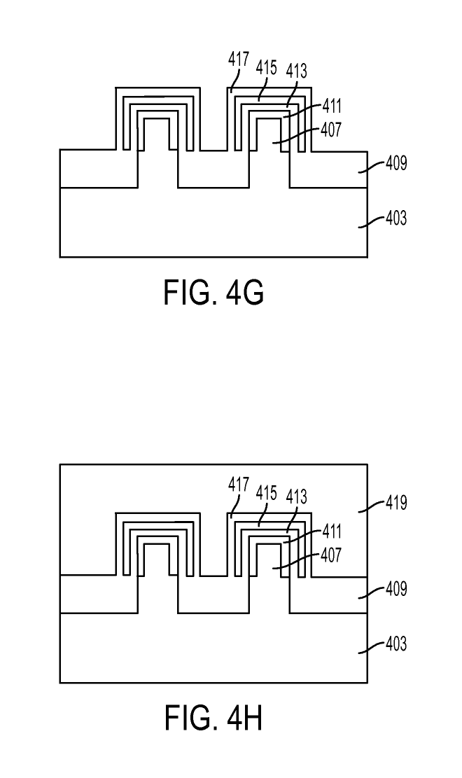

FIGS. 4A through 4H schematically illustrate a process flow for fabricating an n-type full buried channel, in accordance with an exemplary embodiment. Adverting to FIG. 4A, a hard mask layer 401, for example silicon nitride (Si₃N₄), is deposited on a p-type Si substrate 403. Photoresist 405 is formed on hard mask layer 401 and patterned to form openings where FinFET fins are to be formed. The openings may, for example, have dimensions of 50 nm to 500 nm.

Hardmask 401 and Si substrate 403 are etched through photoresist 405, forming FinFET fins 407, as illustrated in FIG. 4B. Fins 407 may for example be formed to a height of 30 nm to 300 nm. Photoresist 405 may then be removed. As illustrated in FIG. 4C, an oxide layer 409, for example a silicon oxide, is then deposited over the entire substrate.

Adverting to FIG. 4D, oxide layer 409 is planarized, e.g., by chemical mechanical polishing (CMP), down to hard mask layer 401. As illustrated in FIG. 4E, a timed etch is then performed, for example by wet etch (such as with diluted HF), for 50 sec to 500 sec, to reduce the thickness of oxide layer 409 to 2 nm to 20 nm. Once oxide layer 409 reaches the desired thickness, hardmask 401 may be removed. The remaining oxide forms shallow trench isolation regions between fins 407.

As illustrated in FIG. 4F, the exposed portions of fins 407 are n-type plasma doped to form buried channel 411. For example, the fins may be doped with n-type dopants at a dosage of 1 E12 to 1 E13 cm⁻² range. Alternatively, a Si epitaxy with in situ n-doping may be performed on fins 407 to form buried channel 411.

A first oxide layer 413, a nitride layer 415, and a second oxide layer 417 are then grown over buried channel 411, forming the ONO portion, as illustrated in FIG. 4H. An additional nitride layer and oxide layer (not shown for illustrative convenience) optionally may be formed on second oxide layer 417, to form an ONONO portion. Oxide layers 413 and 417 may for example be formed of a silicon dioxide (SiO₂) or silicon oxynitride (SiON) layer, at a thickness of 10 angstroms (Å) to 100 Å and 30 Å to 120 Å, respectively. Nitride layer 415 may be formed of Si₃N₄ or Si-rich Si₃N₄, at a thickness of 30 Å to 100 Å.

Adverting to FIG. 4H, polysilicon 419 is deposited over the entire substrate. The resulting structure includes an n-type full buried channel, i.e., carriers at the buried channel are displaced away from the Si—SiO₂ interface, giving the entire channel full immunity against interface defects, thereby further improving endurance.

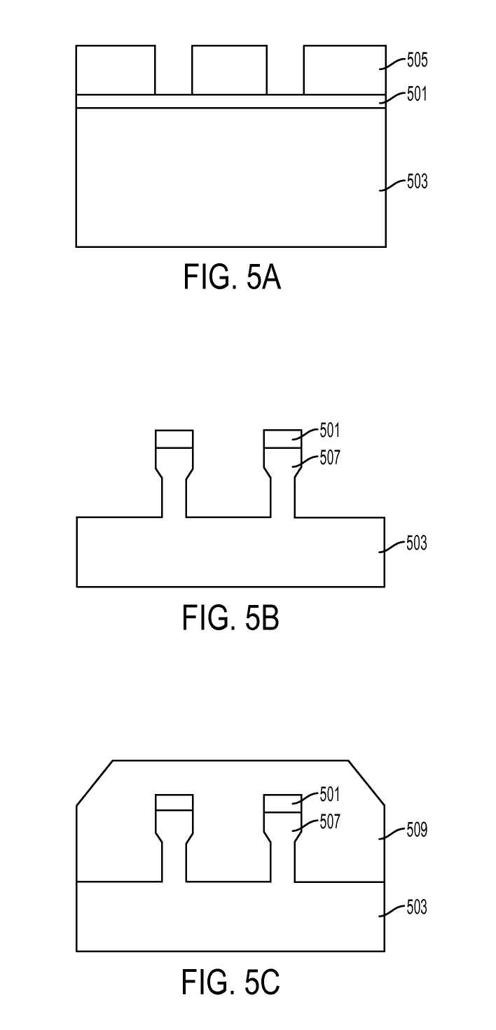

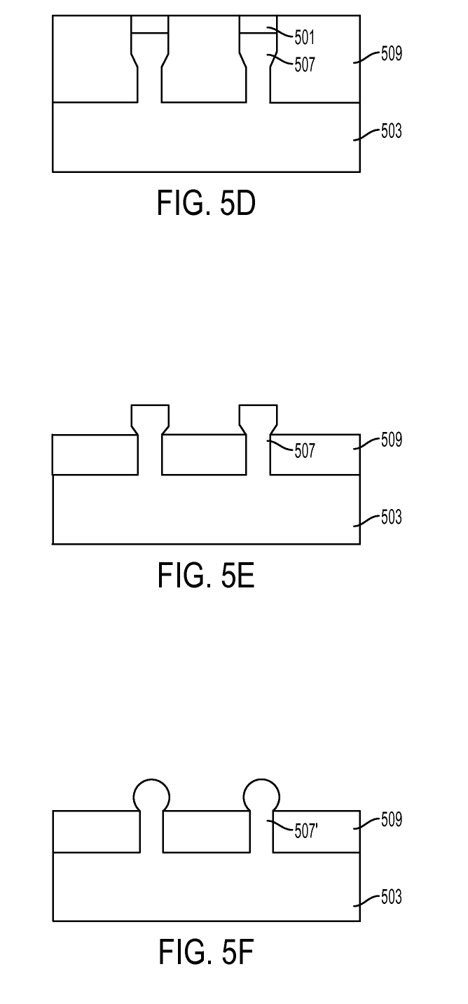

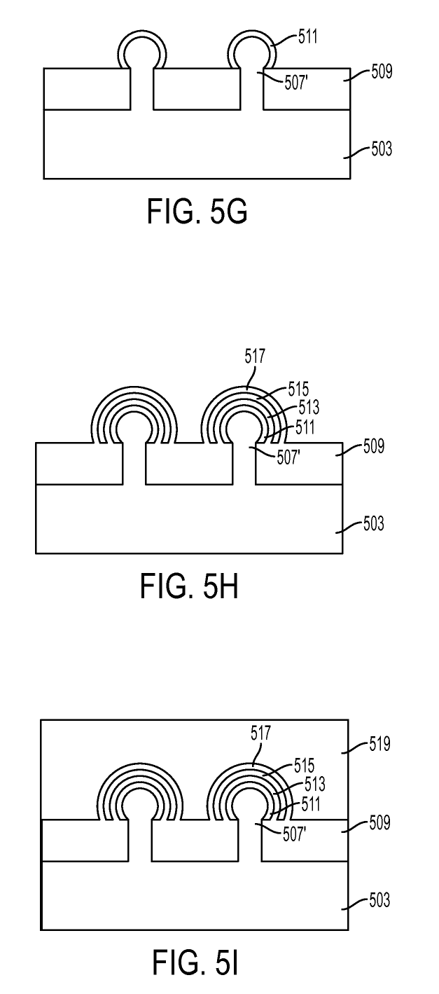

FIGS. 5A through 5I schematically illustrate a process flow for fabricating an n-type full buried channel, in accordance with another exemplary embodiment. The initial process flow of this embodiment is similar to that illustrated in FIG. 4A. A hard mask 501 is deposited on p-type Si substrate 503, and photoresist 505 is formed and patterned on hard mask 501 to form openings, for example with dimensions of 50 nm to 500 nm, as illustrated in FIG. 5A.

Hard mask 501 and Si substrate 503 are etched through the openings in photoresist 505 to form fins 507. An anisotropic etch, for example dry etching, followed by an isotropic etch, e.g., wet etching, are employed to obtain the desired profile, as illustrated in FIG. 5B. Fins 507 may, for example, be formed to a width of 5 nm to 50 nm for a height of 15 nm to 150 nm, and to a width of 3 nm to 30 nm for the remaining height of 15 nm to 150 nm. After the etching is complete, the photoresist may be removed.

Adverting to FIG. 5C, an oxide layer 509, for example SiO₂, is deposited over the entire substrate. Oxide layer 509 is then planarized down to hard mask 501, e.g. by CMP, as illustrated in FIG. 5D.

As illustrated in FIG. 5E, a timed etch is performed, for example by wet etch (such as diluted HF), for 50 sec to 500 sec, to reduce the thickness of oxide layer 509 to approximate the height of the fin's neck region as illustrated in 5D. When, oxide layer 509 reaches the desired thickness, hard mask 501 may be removed. The remaining oxide forms shallow trench isolation regions between fins 507.

The exposed portion of fins 507 is then subjected to an H₂ treatment (H₂ forming gas treatment), for example for 1 min to 10 min, at a temperature of 800° C. to 1100° C., for Si migration to create a round surface, forming fins 507′, as illustrated in FIG. 5F.

As illustrated in FIG. 5G, the exposed portions of fins 507′ are n-type plasma doped to form buried channel 511. For example, the exposed portion may be doped with n-type dopants at a dosage of 1 E12 to 1 E13 cm⁻² range. Alternatively, a Si epitaxy with in situ n-doping may be performed on fins 507′ to form buried channel 511.

The ONO portion is then formed, as illustrated in FIG. 5H. A first oxide layer 513, a nitride layer 515, and a second oxide layer 517 are then grown over buried channel 511. An additional nitride layer and oxide layer (not shown for illustrative convenience) optionally may be formed on second oxide layer 517, forming an ONONO portion. Oxide layers 513 and 517 may for example be formed of SiO₂ or SiON, at a thickness of 10 Å to 100 Å and 30 Å to 120 Å, respectively, and nitride layer 515 may be formed of Si₃N₄ or Si-rich Si₃N₄, at a thickness of 30 Å to 100 Å.

Adverting to FIG. 5I, polysilicon 519 is deposited over the entire substrate. The resulting Ω-shaped structure not only gives the entire channel full immunity against interface defects, but the rounded ONO surface also minimizes fringing field and corner-related defects introduced by edges from the etching process.

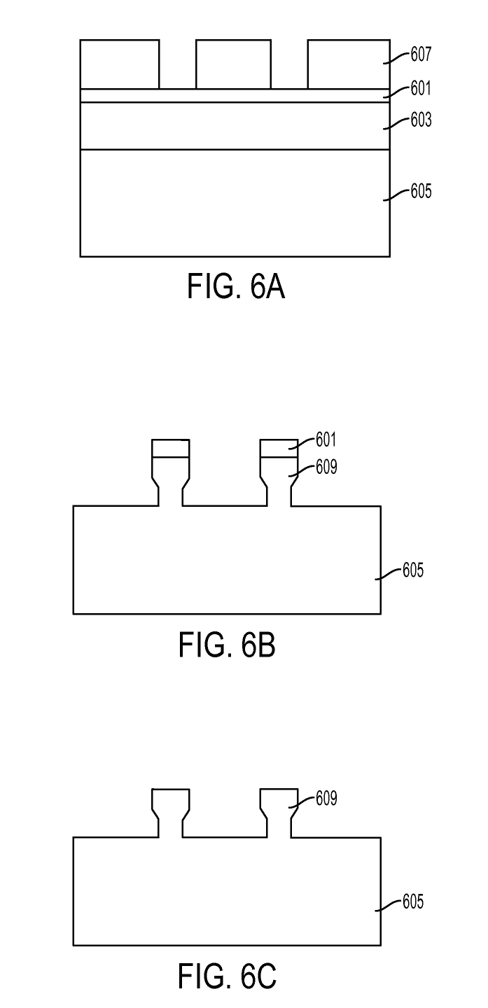

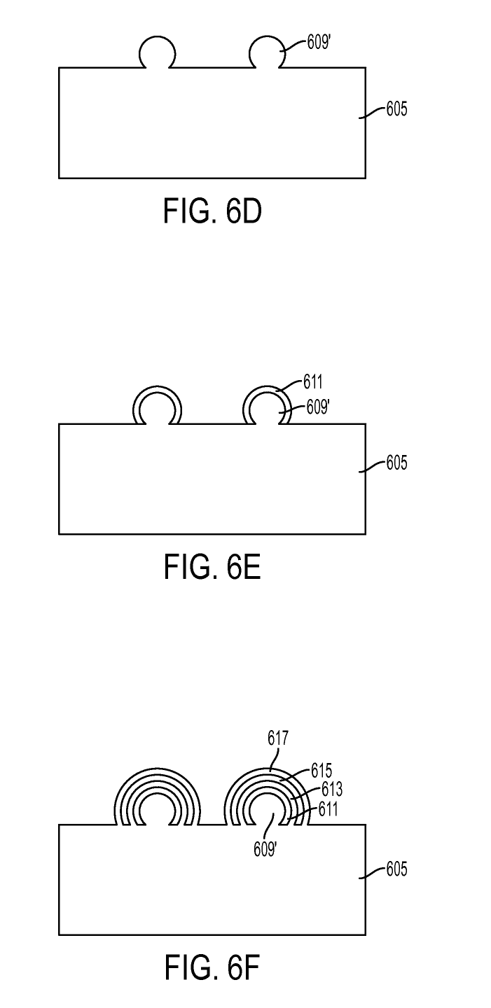

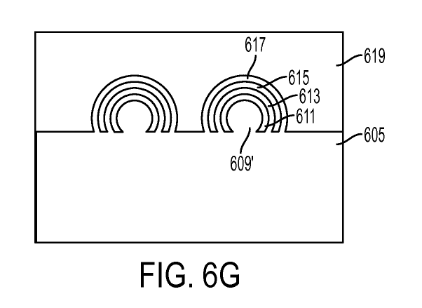

An Ω-shaped n-type full buried channel may alternatively be formed on a silicon on insulator (SOI) substrate, in accordance with another exemplary embodiment, as illustrated in FIGS. 6A through 6G. Adverting to FIG. 6A, a hard mask layer 601 is formed on an SOI substrate (a p-type Si substrate 603 a bulk oxide (BOX) layer 605), and a photoresist 607 is deposited and patterned on hard mask layer 601 to form openings, for example with dimensions of 50 nm to 500 nm.

As illustrated in FIG. 6B, hard mask 601 and Si substrate 603 are etched through the openings in photoresist 607 to form fins 609. An anisotropic etch, for example dry etching, followed by an isotropic etch, e.g., wet etching, are employed to obtain the desired profile. Fins 609 may, for example, be formed to a width of 5 nm to 50 nm for a height of 15 nm to 150 nm, and to a width of 3 nm to 30 nm for the remaining height of 15 nm to 150 nm. After the etching is complete, the photoresist may be removed.

Hard mask 601 may then be removed, as illustrated in FIG. 6C, leaving fins 609 exposed. Adverting to FIG. 6D, fins 609 are subjected to an H₂ treatment, (H₂ forming gas treatment), for example for 1 min to 10 min, at a temperature of 800° C. to 1100° C., for Si migration to create a round surface, forming fins 609′.

As illustrated in FIG. 6E, the fins 609′ are n-type plasma doped to form buried channel 611. For example, the fins may be doped with n-type dopants at a dosage of 1 E12 to 1 E13 cm⁻² range. Alternatively, a Si epitaxy with in situ n-doping may be performed on fins 609′ to form buried channel 611.

A first oxide layer 613, a nitride layer 615, and a second oxide layer 617 are then grown over buried channel 611 to form the ONO portion, as illustrated in FIG. 6F. An additional nitride layer and oxide layer (not shown for illustrative convenience) optionally may be formed on second oxide layer 617, forming an ONONO portion. Oxide layers 613 and 617 may for example be formed of SiO₂ or SiON, at a thickness of 10 Å to 100 Å and 30 Å to 120 Å, respectively, and nitride layer 615 may be formed of Si₃N₄ or Si-rich Si₃N₄, at a thickness of 30 Å to 100 Å.

Adverting to FIG. 6G, polysilicon 619 is deposited over the entire substrate, completing the SONOS structure. In FIG. 6G, the resulting Ω-shaped structure not only gives the entire channel full immunity against interface defects, but also minimizes fringing field and corner-related defects with the rounded ONO surface.

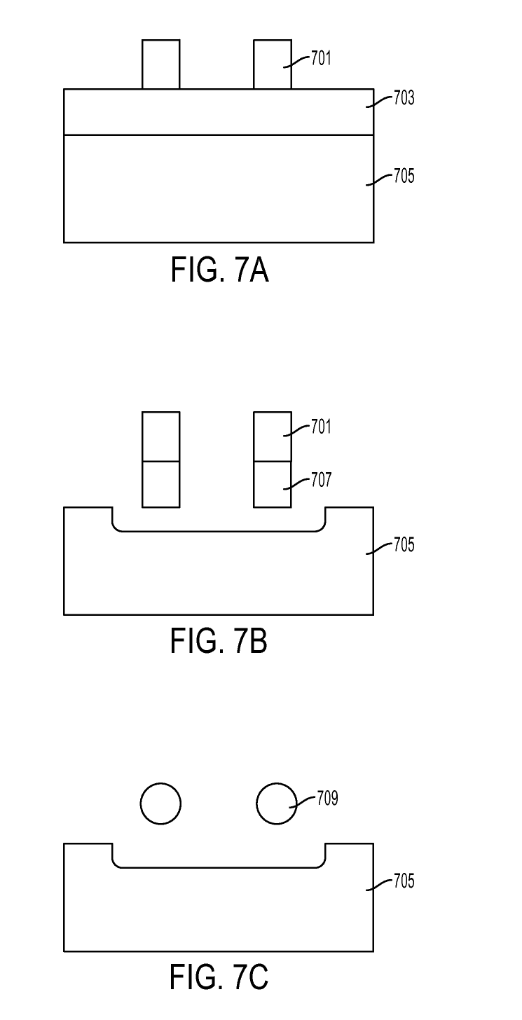

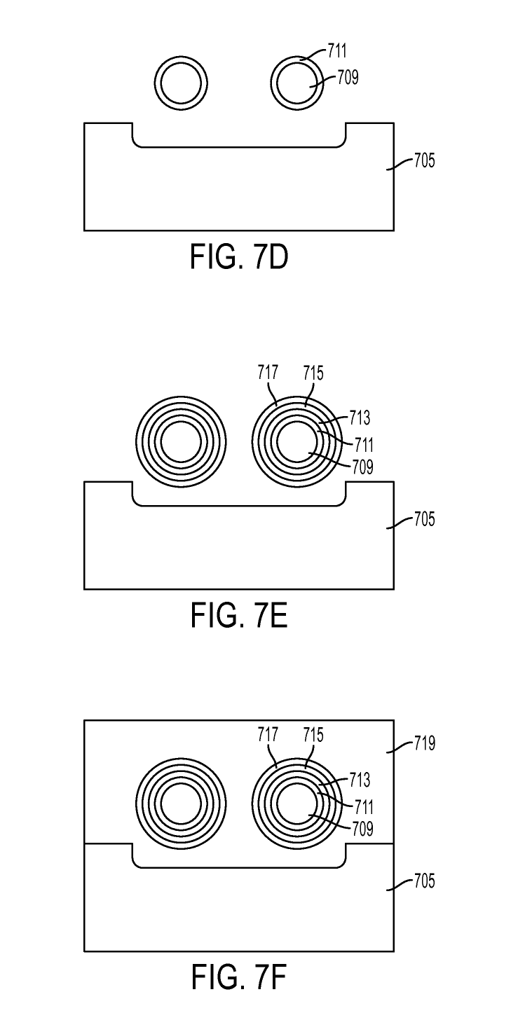

FIGS. 7A through 7F schematically illustrate a process flow for fabricating an n-type full buried channel nano-wire, in accordance with another exemplary embodiment. Adverting to FIG. 7A, a photoresist 701 is formed and patterned on an SOI substrate including p-type Si substrate 703 on BOX layer 705. Photoresist 701 is patterned with portions where fins are to be formed.

As illustrated in FIG. 7B, by applying dry etching for the fin-etching, followed by wet etching by diluted HF for removal of the oxide undercut, for 1 min to 10 min at a temperature of room temperature to 75° C., fins 707 are etched. Also, BOX layer 705 is undercut below fins 707.

Photoresist 701 may then be removed, as illustrated in FIG. 7C. An H₂ treatment (H₂ forming gas treatment), for example for 1 min to 10 min, at a temperature of 800° C. to 1100° C., is performed on fins 707 to create nano-wires 709.

Adverting to FIG. 7D, nano-wires 709 are n-type plasma doped to form buried channel 711. For example, the fins may be doped with n-type dopants at a dosage of 1 E12 to 1 E13 cm⁻² range. Alternatively, a Si epitaxy with in situ n-doping may be performed on nano-wires 709 to form buried channel 711.

Subsequently, as illustrated in FIG. 7E, a first oxide layer 713, a nitride layer 715, and a second oxide layer 717 are then grown over buried channel 711 to form the ONO portion. An additional nitride layer and oxide layer (not shown for illustrative convenience) optionally may be formed on second oxide layer 717, forming an ONONO portion. Oxide layers 713 and 717 may for example be formed of SiO₂ or SiON, at a thickness of 10 Å to 100 Å and 30 Å to 120 Å, respectively, and nitride layer 715 may be formed of Si₃N₄ or Si-rich Si₃N₄, at a thickness of 30 Å to 100 Å.

As illustrated in FIG. 7F, polysilicon 719 is deposited over the entire substrate, completing the SONOS structure. The resulting round ONO surface of the nano-wire structure, like the Ω-shaped full buried channels, not only gives the entire channel full immunity against interface defects, but also minimizes fringing field and corner-related defects.

The embodiments of the present disclosure can achieve several technical effects, full channel immunity against interface defects and minimized fringing field and corner-related defects, and thereby improved P/E cycling endurance. The present disclosure enjoys industrial applicability in any of various types of highly integrated semiconductor devices such as non-volatile memory devices, particularly sub-30 nm devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming p-type silicon fins protruding from a first oxide layer;
forming an n-type silicon layer over exposed surfaces of the fins;
forming a second oxide layer, a nitride layer, and a third oxide layer sequentially on the n-type silicon layer; and
forming a polysilicon layer on the third oxide layer.

2. The method according to claim 1, comprising forming the n-type silicon layer by n-type plasma doping the fins or by epitaxially growing in-situ n-doped silicon on the fins.

3. The method according to claim 2, comprising:
forming the fins in a p-type silicon substrate; and
forming the first oxide layer on the p-type silicon substrate around the fins.

4. The method according to claim 3, comprising forming the first oxide layer by:
depositing an oxide over the substrate and the fins; and
time etching the oxide to a thickness of 2 nm to 20 nm.

5. The method according to claim 4, comprising forming the p-type silicon fins by:
forming a hard mask on the p-type silicon substrate;
patterning a photoresist on the hard mask with openings;
etching the p-type silicon substrate through the openings in the patterned photoresist; and
removing the photoresist.

6. The method according to claim 5, further comprising:
planarizing the deposited oxide and subsequently time etching the oxide; and
removing the hard mask after time etching the oxide, prior to forming n-type silicon layer.

7. The method according to claim 4, comprising forming the p-type silicon fins by:
forming a hard mask on the p-type silicon substrate;
patterning a photoresist with openings on the hard mask;
anisotropically etching followed by isotropically etching the p-type silicon substrate through the openings, thereby forming fins;
removing the photoresist and the hard mask; and
creating a round top surface for each fin.

8. The method according to claim 7, comprising creating the round top surface for each fin by H₂ treating.

9. The method according to claim 2, comprising:
forming a p-type silicon substrate on a bulk oxide (BOX) layer; and
forming the fins in the silicon substrate.

10. The method according to claim 9, comprising forming the p-type silicon fins by:
forming a hard mask on the p-type silicon substrate;
patterning a photoresist with openings on the hard mask;
anisotropically etching followed by isotropically etching the p-type silicon substrate through the openings, thereby forming fins;
removing the photoresist and the hard mask; and
creating a round top surface for each fin.

11. The method according to claim 10, comprising creating the round top surface for each fin by H₂ treating.

12. A device comprising:
a first oxide layer;
p-type silicon fins protruding from the first oxide layer;
an n-type silicon layer over exposed surfaces of the fins;
a second oxide layer, a nitride layer, and a third oxide layer sequentially formed on the n-type silicon layer; and
a polysilicon layer on the third oxide layer.

13. The device according to claim 12, comprising a p-type silicon substrate under the first oxide layer, wherein the fins extend from the p-type silicon substrate and through the first oxide layer.

14. The device according to claim 13, wherein each fin comprises a rounded top surface.

15. The device according to claim 12, wherein:
the first oxide layer comprises a bulk oxide layer; and
each fin comprises a rounded top surface.

16. A method comprising:
forming a p-type silicon substrate on a bulk oxide layer;
forming nano-wires from the silicon substrate;
forming an n-type silicon layer around the nano-wires;
forming a second oxide layer, a nitride layer, and a third oxide layer sequentially on the n-type silicon layer; and
forming a polysilicon layer on the third oxide layer.

17. The method according to claim 16, comprising forming the nano-wires by:
patterning a photoresist on the silicon substrate;
etching the silicon substrate through the patterned photoresist and undercutting the bulk oxide layer;
removing the photoresist; and
H₂ treating each fin.

18. The method according to claim 17, comprising forming the n-type silicon layer by n-type plasma doping the fins or by epitaxially growing in-situ n-doped silicon on the fins.

19. A device comprising:
p-type silicon nano-wires;
an n-type silicon layer around the nano-wires;
a first oxide layer, a nitride layer, and a second oxide layer sequentially formed on the n-type silicon layer; and
a polysilicon layer on the third oxide layer.

20. The device according to claim 19, comprising a bulk oxide layer under the polysilicon layer, wherein the bulk oxide layer is undercut below the nano-wires.
